(19) United States
(12) Patent Application Publication
(10) Pub. No.: US 2021/0134853 A1
(43) Pub. Date: May 6, 2021

(54) METHOD FOR MANUFACTURING DISPLAY DEVICE

(71) Applicant: InnoLux Corporation, Miao-Li County (TW)

(72) Inventors: Hsin-Hao Huang, Miao-Li County (TW); Sheng-Hui Chiu, Miao-Li County (TW); Yu-Chih Tseng, Miao-Li County (TW)

(21) Appl. No.: 16/675,189

(22) Filed: Nov. 5, 2019

(51) Int. Cl. H01L 27/12

(52) U.S. Cl. CPC H01L 27/1266; C23C 16/01

(57) ABSTRACT

A method for manufacturing a display device is disclosed, the method at least includes the following step: Firstly, a temporary substrate is provided, a hydrogen containing structure is formed on the temporary substrate, a polymer film is formed on the hydrogen containing structure, and a display element is formed on the polymer film. Afterwards, a laser beam process is performed, to focus a laser beam on the hydrogen containing structure, and the temporary substrate is then removed.

### BACKGROUND OF THE DISCLOSURE

### 1. Field of the Disclosure

The present disclosure relates to a method for manufacturing a display device. More particularly, the present disclosure relates to a method of separating a layer or a substrate from a display device.

### 2. Description of the Prior Art

As a current display device, a liquid crystal display (LCD), a plasma display panel (PDP), an active matrix organic light emitting display (AM OELD), and the like have been used.

Display devices such as smartphones, tablets, notebooks, monitors, and TVs, have become indispensable necessities in modern society. With the flourishing development of such portable electronic products, consumers have high expectations regarding the quality, functionality, or price of such products. These electronic products are often provided with communications capabilities.

However, some difficulties may be encountered in the manufacture of the display devices. Accordingly, a method for manufacturing the display devices that improves display quality is needed.

### SUMMARY OF THE DISCLOSURE

The present disclosure provides a method for manufacturing a display device, the method at least includes the following steps: Firstly, a temporary substrate is provided, a hydrogen containing structure is formed on the temporary substrate, a polymer film is formed on the hydrogen containing structure, and a display element is formed on the polymer film. Afterwards, a laser beam process is performed, to focus a laser beam on the hydrogen containing structure, and the temporary substrate is then removed.

The present disclosure provides a method for separating a display device (e.g. a flexible display device) from a supporting substrate, without deforming or damaging the display device when debonding the display device formed on the supporting substrate. By the method provided by the present disclosure, the quality or production yield of the display device can be improved.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIGS. 1-2 show the schematic diagrams of a display device according to a first embodiment of the present disclosure.

FIG. 3 shows the effect of different energy densities (mJ/cm²) on the pull up force value for a fixed thickness of hydrogen containing structure irradiated by a laser lift-off (LLO) process.

FIG. 4 shows the effect of the LLO process irradiation with different energy density (mJ/cm²) on the pull up force for different thickness of hydrogen containing structure.

FIG. 5 shows the energy density (mJ/cm²) required for the LLO process in order to successfully pull the hydrogen containing structure with different thicknesses.

FIG. 6 is the data table recording the pull up force required for different thicknesses of hydrogen containing structure to be pulled successfully after irradiating laser with different energy densities.

FIGS. 7-8 show SEM (scanning electron microscope) cross-sectional views of the surface of different display devices according to various embodiments.

FIG. 9 shows the schematic diagrams of a display device according to a second embodiment of the present disclosure.

FIGS. 10-11 show the schematic diagrams of a display device according to a third embodiment of the present disclosure.

FIG. 12 shows the flow chart of the method for separating a display device from a supporting substrate.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the touch display device, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”.

It will be understood that when an element or layer is referred to as being “on” or “connected to” another element or layer, it can be directly on or directly connected to the other element or layer, or intervening elements or layers may be presented. In contrast, when an element is referred to as being “directly on” or “directly connected to” another element or layer, there are no intervening elements or layers presented.

It should be noted that the technical features in different embodiments described in the following can be replaced, recombined, or mixed with one another to constitute another embodiment without departing from the spirit of the present disclosure.

In addition, the phrase “in a range from a first value to a second value” indicates the range includes the first value, the second value, and other values in between.

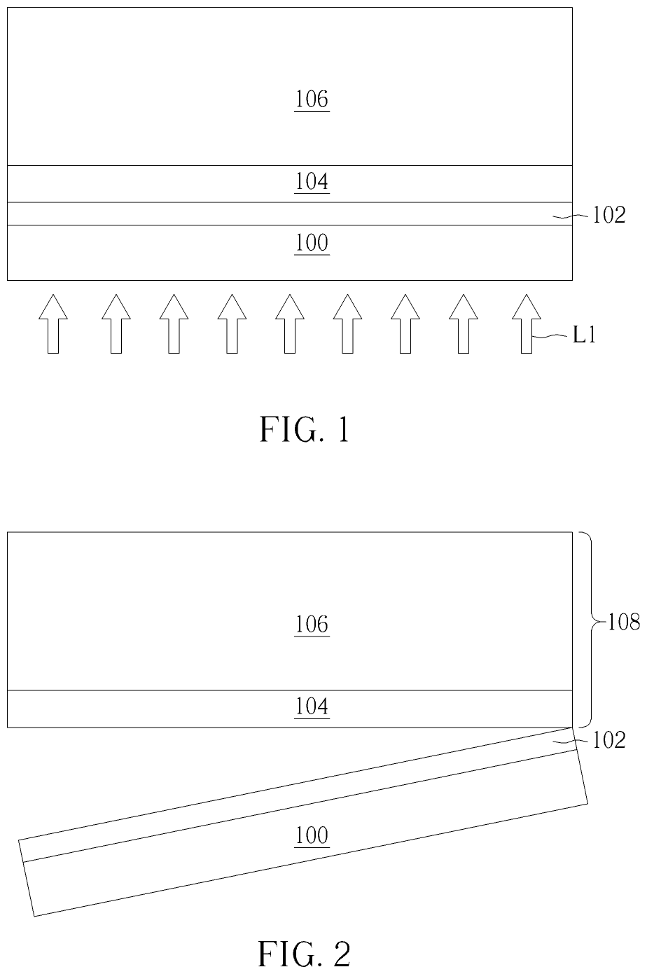

Referring to FIGS. 1-2, which show the schematic diagram of a display device according to a first embodiment of the present disclosure. In the first embodiment of the preset disclosure, a temporary substrate 100 is provided, and a hydrogen containing structure 102 is formed on the temporary substrate 100. Besides, a polymer film 104 is formed on the hydrogen containing structure 102, and a display element 106 is formed on the polymer film 104. In this embodiment, the polymer film 104 may directly contact the hydrogen containing structure 102.

In this embodiment, the temporary substrate 100 may include a glass substrate, ceramic substrate, other suitable substrates, or a combination thereof. The temporary substrate 100 may be a rigid substrate. The material of the temporary substrate 100 may include suitable transparent materials, and a transmittance of the temporary substrate 100 at the peak wavelength is greater than 0.75 (which means, when a light source penetrates the temporary substrate 100, the ratio of the intensity of the light source passing through to the intensity of the original light source is above 75%) and less than or equal to 1 (0.75<transmittance≤1). The hydrogen containing structure 102 can include an amorphous silicon (a-Si) layer for example, which contains hydrogen (H). However, the present disclosure is not limited thereto, the hydrogen containing structure 102 may comprise other suitable materials, such as nitride (e.g. SiNx), polymer or a combination thereof. In this embodiment, the hydrogen containing structure 102 include an amorphous silicon film, and in the following steps, the temporary substrate 100 and the hydrogen containing structure 102 will be removed from the polymer film 104.

The polymer film 104 may be a flexible transparent layer, in one embodiment of the present disclosure, the polymer film 104 can include a polyimide film, but not limited thereto. The polymer film 104 can be used as a protective layer or a substrate for the display element 106, to protect the components of the display element 106 (such as some thin film transistors, TFTs). The display element 106 can include any element used in a display device. For example, the display element 106 can include a liquid crystal (LC) cell, an organic light emitting diode (OLED), quantum dots light emitting diode (QLED or QD-LED), an inorganic light emitting diode (LED), micro LED, mini LED, quantum dot (QD), fluorescence, phosphor, other suitable display elements, or a combination thereof. Other electronic elements may be formed between the polymer film 104 and the display element 106, but not limited thereto.

In the present disclosure, the purpose for forming the temporary substrate 100 and the hydrogen containing structure 102 under the polymer film 104 is to improve the structural strength of the display devices during the manufacturing process or to improve the process yield. It can be described more detail in the following paragraphs:

The display device may include a flexible display device, a touch display device, a curved display device, a tiled display device, other suitable display device, or a combination thereof, but it is not limited thereto. The display device may include a flexible substrate. However, a flexible substrate may be curved during various manufacturing processes, and the alignment may be deviated.

To improve the accuracy of the alignment, a temporary bonding/debonding scheme may be suggested. In a manufacturing process of the display device, a flexible substrate (e.g. the polymer film 104) may be formed or bonded on a supporting substrate (e.g. the temporary substrate 100) for the subsequent processes by a coating process or a laminating process. The flexible substrate may be debonded from the supporting substrate when some of the processes are finished.

In case where there is no hydrogen containing structure, one method of separating the temporary substrate 100 from the polymer film 104 is to focus a laser beam L1 on the polymer film 104 to break the bonds between the polymer film 104 and the temporary substrate 100 (the method can also be called as a laser lift-off process (LLO) in the following paragraphs). However, according to the applicant's experimental results, it is found that when the polymer film 104 is directly irradiated by the laser beam, some ashes will be remained on the exposed surface of the polymer film 104. Since other components need to be formed on the surface of the polymer film 104 (for example, a polarizer) in the subsequent processes, if ashes are left on the surface of the polymer film 104, it will be disadvantageous for subsequent formation of other components.

Therefore, the residual ashes may need to be reduced. In another embodiment of the present disclosure, as shown in FIGS. 1-2, a hydrogen containing structure 102 may be formed between the polymer film 104 and the temporary substrate 100. At least one laser beam L1 may be focused on the hydrogen containing structure 102 when removing the temporary substrate 100 from the polymer film 104. The hydrogen containing structure 102 can be formed by, for example, a chemical vapor deposition (CVD) process, a low-pressure CVD process or a plasma CVD process. After forming the display element 106, the hydrogen containing structure 102 (such as an a-Si layer) is irradiated and heated by the laser beam L1 through the transparent temporary substrate 100 to separate the polymer film 104 from the hydrogen containing structure 102. More detail, in this case, the hydrogen containing structure 102 includes hydrogen, and the hydrogen gas generated by the laser irradiation separates the polymer film 104 and the hydrogen containing structure 102. In this embodiment, a peak wavelength of the laser beam L1 ranges from 306 nm to 310 nm, such as 308 nm, and an energy intensity of the laser beam L1 is greater than 400 mJ/cm², but the present disclosure is not limited thereto.

In this embodiment, the hydrogen containing structure 102 includes an amorphous silicon film which may contain hydrogen (H). In one embodiment of the present disclosure, the H content is about 10 to 30 atomic %. In this way, with a predetermined content of hydrogen, hydrogen gas is released by irradiation of the laser beam L1 to generate internal pressure in the hydrogen containing structure 102, thereby causing force to separate the hydrogen containing structure 102 and the polymer film 104. The hydrogen (H) content of the amorphous silicon film can be adjusted by appropriately setting deposition conditions, for example, such as the gas composition, gas pressure, gas atmosphere, gas flow rate, temperature, substrate temperature, input power, etc. In this embodiment, to avoid laser light crystallizing the amorphous silicon and efficiently release hydrogen gas, a thickness of the hydrogen containing structure 102 (the amorphous silicon film) may be greater than or equal to 30 nm and less than 50 nm. The thickness of the hydrogen containing structure 102 may be measured as an averaged thickness of 3 to 5 thicknesses in a cross-sectional view. In addition, during the process of forming the hydrogen containing structure 102, hydrogen gas is introduced into a chamber (not shown).

The following paragraphs show some experimental data of the present disclosure, such as the data of adjusting the thickness of the hydrogen containing structure 102, executing the LLO process at different steps, and changing the temperature of the LLO process, etc. The effect of adjusting the above parameters on the LLO process has been observed and recorded. In more detail, in the following experiments, a pull up test will be performed on the hydrogen containing structure 102. If the numerical result of the required pull up force is small, it is easier to remove the hydrogen containing structure 102 (that is, to separate the hydrogen containing structure 102 and the polymer film 104 from each other). On the contrary, if the numerical result of the required pull up force is large, it is harder to remove the hydrogen containing structure 102 from the surface of the polymer film 104.

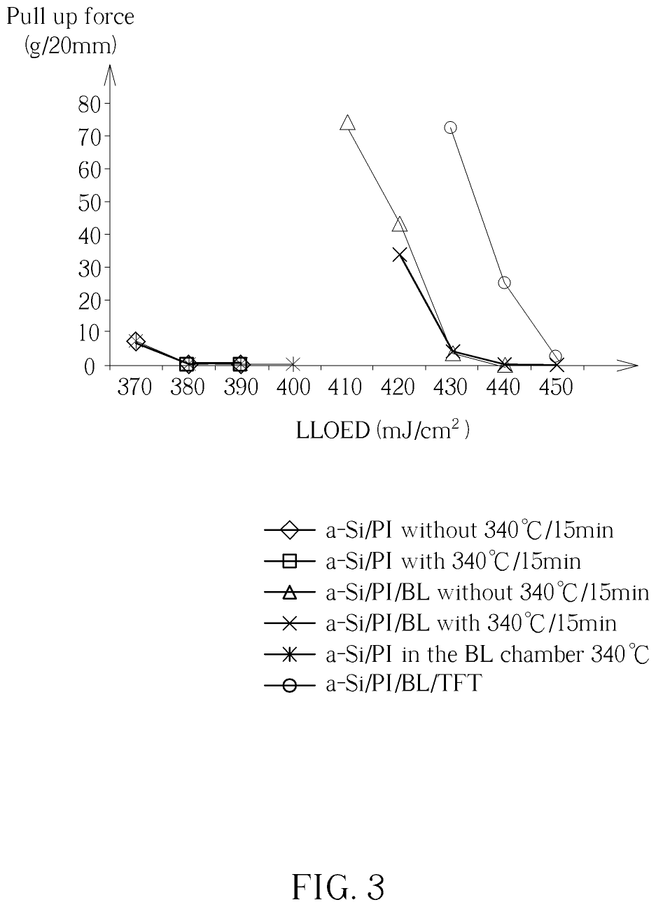

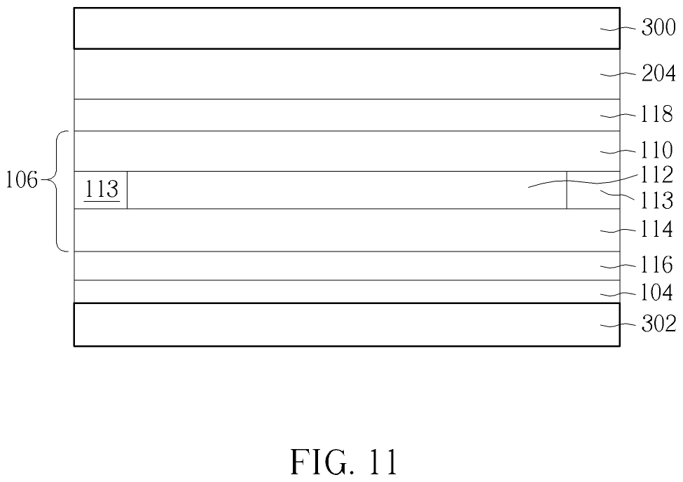

As shown in FIG. 3, FIG. 3 shows the minimum required pull up forces for the hydrogen containing structure 102 with fixed thickness and irradiated with different energy densities (mJ/cm²) in the LLO process. In FIG. 3, taking the hydrogen containing structure 102 with a thickness of 500 angstroms (Å) as an example, lasers with different energy densities are irradiated on the hydrogen containing structure 102, and a pull up test is then performed on the hydrogen containing structure 102 to measure the minimum required pull up force for removing the hydrogen containing structure 102 from the surface of the polymer film 104. The horizontal axis of FIG. 3 represents the energy densities of the LLO processes (hereinafter referred to as “LLOED” (laser lift-off energy density) shown in FIG. 3), and the unit is mJ/cm², while the vertical axis represents the pull up forces, and the unit is g/20 mm. In addition, in the experimental data of FIG. 3, part of the data are labeled as “/PI” in FIG. 3, and these data represent that the pull up test is performed on the hydrogen containing structure 102 after the polymer film 104 is formed on the hydrogen containing structure 102; part of the data are labeled as “/PI/BL” in FIG. 3, and these data represent that the pull up test is performed on the hydrogen containing structure 102 after a buffer layer (e.g. the buffer layer 116 shown in the following FIG. 10), the polymer film 104 and the hydrogen containing structure 102 are formed; part of the data are labeled as “/PI/BL/TFT” in FIG. 3, and these data represent the pull up test is performed on the hydrogen containing structure 102 after a thin film transistor (TFT) layer (e.g. the thin film transistor layer 114 shown in the following FIG. 10), the buffer layer (e.g. the buffer layer 116 shown in the following FIG. 10), the polymer film 104 and the hydrogen containing structure 102 are formed.

In this example, the sample size is 10 cm×10 cm, that is, the area of the hydrogen containing structure 102 is 100 cm²; the temporary substrate 100 uses 0.5 mm glass; the material of the hydrogen containing structure 102 contains amorphous silicon (represented as “a-Si” in the FIG. 3). In this example, the hydrogen containing structure 102 is formed by a CVD process. The material of the polymer film 104 contains PI (polyimide) with a thickness of about 13 μm. The material of the buffer layer (e.g. the buffer layer 116 shown in FIG. 10) includes silicon nitride or silicon oxide, and the temperature for forming the buffer layer 116 is about 340° C. However, it is understood that the above parameters are only an example of the present disclosure, and the present disclosure is not limited thereto.

In addition, during the experiment in FIG. 3, some experimental groups are heated (e.g. at a temperature of about 340° C. for 15 minutes) and then subjected to pull up test. As shown in FIG. 3, the heating treatment has little effect on the pull up test results. For example, the curve of the group of a-Si/PI without 340° C./15 min is substantially overlapped with the curve of the group of a-Si/PI with 340° C./15 min. In other words, regardless of whether the heating treatment is carried out or not, approximately the same pulling up force is required to remove the hydrogen containing structure 102 after the irradiation with the same energy density.

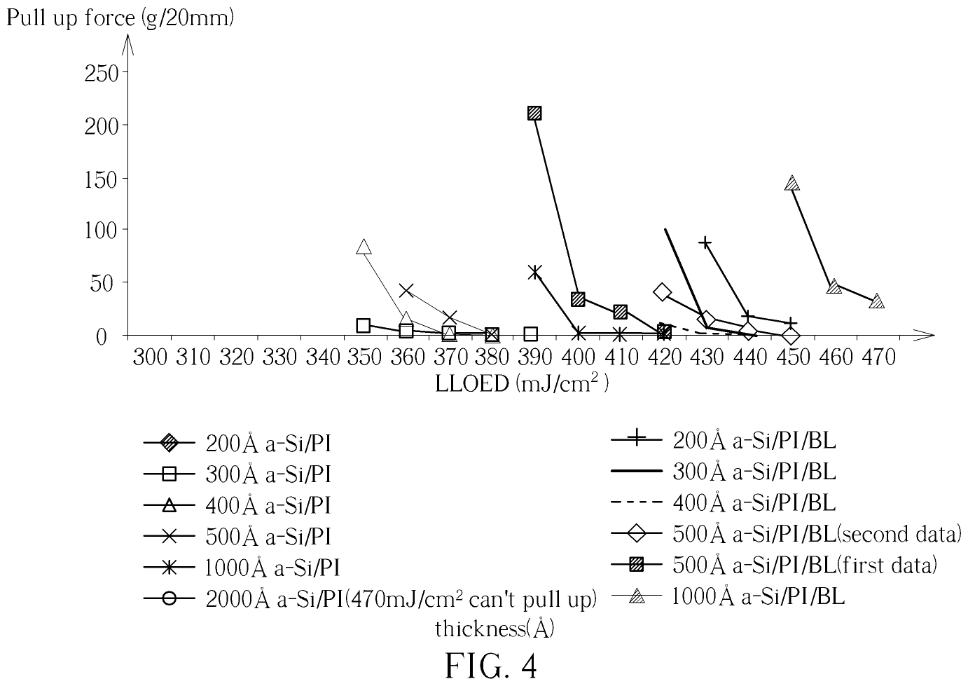

As shown in FIG. 4, FIG. 4 shows the minimum required pull up forces for the hydrogen containing structures 102 with different thickness and irradiated with different energy densities (mJ/cm²) in the LLO process. As shown in FIG. 4, the thicknesses of the hydrogen containing structures 102 are adjusted (the thickness of the hydrogen containing structures 102 ranges from 200 angstroms to 2000 angstroms), and laser with different energy densities are applied on the hydrogen containing structures 102 with different thicknesses. Afterwards, a pull up test is performed on the hydrogen containing structure 102 to measure the minimum required pull up force for removing the hydrogen containing structure 102. The horizontal axis of FIG. 4 represents the energy densities of the LLO processes (hereinafter referred to as LLOED), and the unit is mJ/cm², while the vertical axis represents the pull up forces, and the unit is g/20 mm. In addition, some data in FIG. 4 are labeled as “/PI” or “PI/BL”, the definitions of which are similar to those described in FIG. 3 above and will not be repeated here.

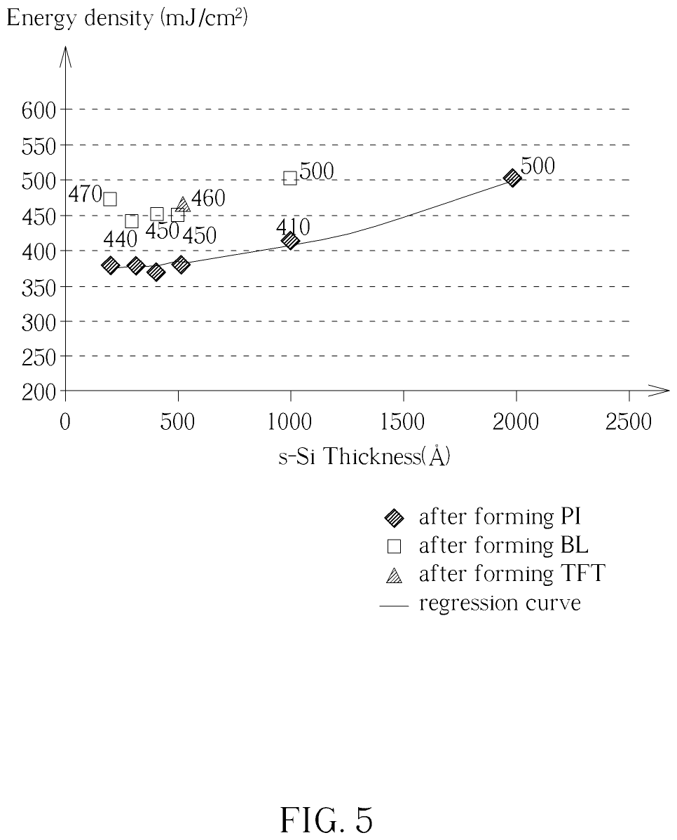

FIG. 5 shows the minimum required energy densities (mJ/cm²) of the LLO process for successfully separate the hydrogen containing structure 102 from the surface of the polymer film 104. In FIG. 5, the horizontal axis represents the thicknesses of the hydrogen containing structure 102, and the unit is angstroms; while the vertical axis represents the energy densities of the LLO process (LLOED), and the unit is mJ/cm². In addition, the definitions of “after forming PI”, “after forming BL” or “after forming TFT” shown in FIG. 5 are similar to the definitions of “/PI”, “/BL” and “/TFT” in FIG. 3 respectively, and will not be repeated here. In FIG. 5, each experimental data is marked on the graph, and a regression curve is calculated to estimate how much energy density (mJ/cm²) may be required for different hydrogen containing structures in the LLO process to successfully pull up the hydrogen containing structures.

From the experimental results from FIG. 4 to FIG. 5, it can be seen that the greater the thickness of the hydrogen containing structure 102 is, the greater the energy density required for the irradiation when performing the LLO process is to successfully remove the hydrogen containing structure 102. On the other hand, if the energy density of the irradiation is lower when the LLO process is performed, stronger pulling up force is required to remove the hydrogen containing structure 102. However, it is worth noting that if the thickness of the hydrogen containing structure 102 exceeds a certain value (for example, when the thickness exceeds 2,000 angstroms), even if the energy density of the LLO process is increased (for example, 470 mJ/cm²), during the pull up test, the applicant found that the hydrogen containing structure 102 is likely to break during the pull up test and cannot pull up the hydrogen containing structure 102 completely. Therefore, the thickness of the hydrogen containing structure 102 is too large, it may be difficult to remove the hydrogen containing structure 102.

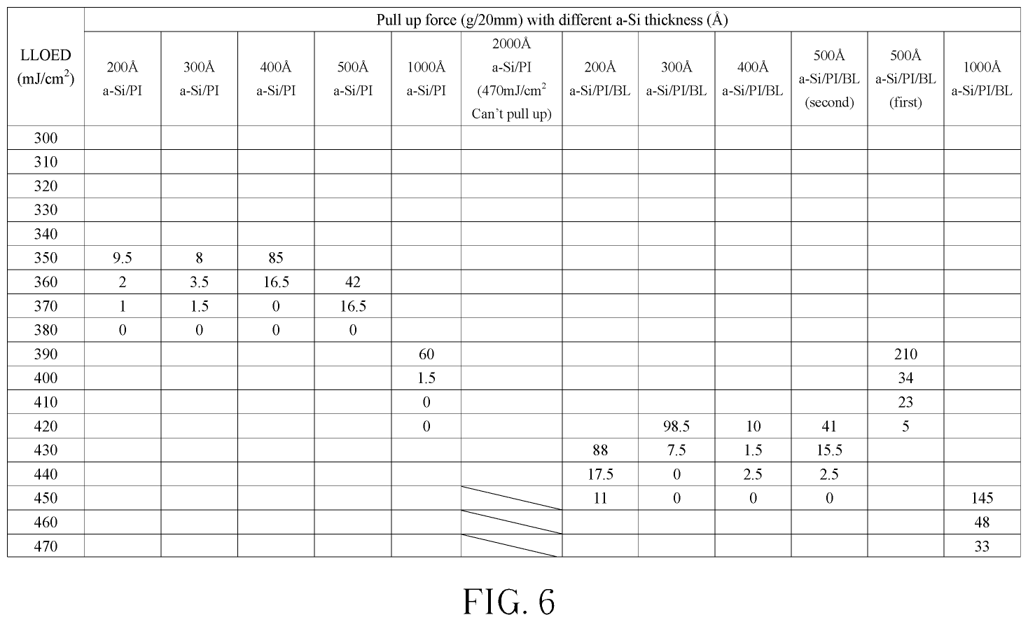

FIG. 6 is the data table recording the pull up force required for the hydrogen containing structures 102 having different thicknesses to be pulled successfully after irradiating laser with different energy densities. In FIG. 6, the results of each group of pull up tests were observed. It was found that the thickness of the hydrogen containing structure 102 may be chosen to be in a range between 300 angstroms and 500 angstroms, that is, 30 nm to 50 nm, such as 350 angstroms, 400 angstroms, or 450 angstroms, but not limited thereto. However, the LLO energy density may need to be greater than 400 mJ/cm², and the energy density may be chosen to be in a range between 420 mJ/cm² and 450 mJ/cm², such as 430 mJ/cm² or 440 mJ/cm², but not limited thereto.

Based on the above experimental results, the applicant found the following conclusions:

1. If the thickness of the hydrogen containing structure 102 is relatively thick, the LLO process may require relatively high the energy density to remove the temporary substrate 100.

2. When the LLO process is carried out after forming the polymer film 104, the thickness of the hydrogen containing structure 102 may be chosen to be in a range between 200 angstroms and 500 angstroms. When the LLO process is carried out, the required energy density may be about 380 mJ/cm², but not limited thereto.

3. When the LLO process is performed after the polymer film 104 and buffer layer 116 are formed, the thickness of the hydrogen containing structure 102 may be chosen in a range between 200 and 500 angstroms. When the LLO process is performed, the required energy density may be in a range from about 420 mJ/cm² to 450 mJ/cm², but not limited thereto.

4. When the LLO process is performed after forming the polymer film and the buffer layer, compared with the LLO process performed after forming the polymer film, the additional required energy density may be chosen to be in a range from about 60 mJ/cm² to 80 mJ/cm².

5. When the LLO process is performed after forming the polymer film, the buffer layer and the TFT layer, compared with the LLO process performed after forming the polymer film, the additional required energy density may be chosen to be in a range from about 90 mJ/cm² to 100 mJ/cm².

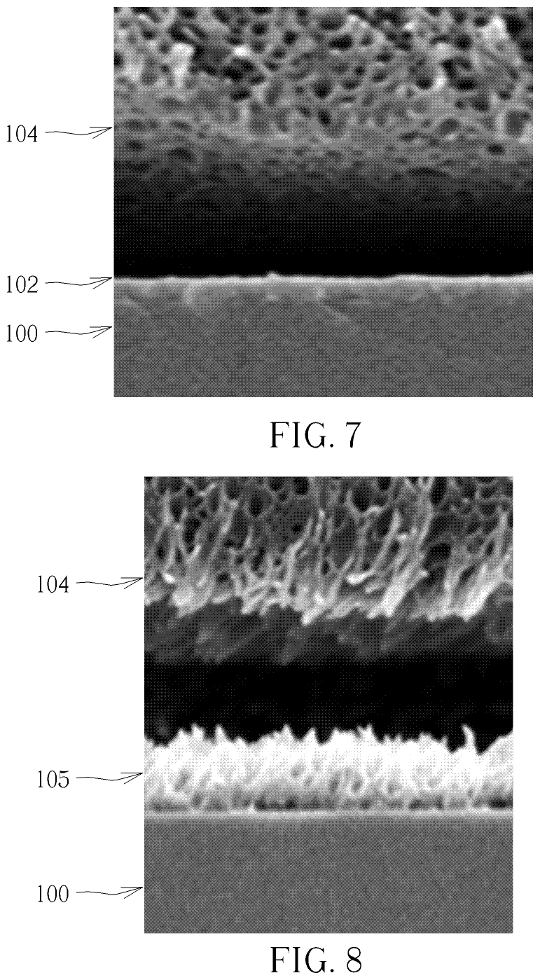

Applicants have found that the thickness and hydrogen content of the hydrogen containing structure 102 may affect of the residual ashes. In more detail, since the hydrogen containing structure 102 disposed between the polymer film 104 and the temporary substrate 100 in the present disclosure, if the thickness of the hydrogen containing structure 102 is insufficient, the hydrogen content of the hydrogen containing structure 102 may be not enough to separate the hydrogen containing structure 102 from the polymer film 104. FIGS. 7-8 show scanning electron microscope (SEM) images of the structure of different display devices in cross-sectional views according to various embodiments. As shown in FIG. 7, in this embodiment, the thickness of the hydrogen containing structure 102 (which is an amorphous silicon film as an example) on the temporary substrate 100 is greater than 30 nm and less than 50 nm (e.g. 40 nm). After focusing a laser beam on the hydrogen containing structure 102, the polymer film 104 has a substantially smooth surface without residual ashes, and the roughness (Ra) of the surface of the polymer film 104 is less than 5 nm and greater than 0 nm, but not limited thereto. However, in another case, as shown in FIG. 8, there is no hydrogen containing structure disposed between the polymer film 104 and the temporary substrate 100. After focusing a laser beam on the polymer film 104, when viewed from the SEM cross-section view (FIG. 4), some ashes 105 are remained on the surface of the polymer film 104, and the roughness (Ra) of the surface of the polymer film 104 is greater than 12 nm

In some embodiments of the preset disclosure, hydrogen can be contained in the hydrogen containing structure 102 according to the process conditions. In one example, hydrogen ions may be implanted after the hydrogen containing structure 102 is formed. Therefore, at least a predetermined amount of hydrogen can be contained in the amorphous silicon film regardless of the process conditions for amorphous silicon.

It is worth noting that after the hydrogen containing structure 102 is focused by the laser beam L1, it may become easy to be removed, and during the step of removing the hydrogen containing structure 102, the temporary substrate 100 may be also removed. In this step, the remaining display element 106 and the polymer film 104 can be defined as a display device 108, and the remaining display device 108 (the polymer film 104 and the display element 106) will be subjected to subsequent steps, such as attaching a polarizer or combining with a backlight module to produce the desired display device.

The following description will detail the different embodiments of the method for forming a display device of the present disclosure. To simplify the description, the following description will detail the dissimilarities among the different embodiments, and the identical features will not be redundantly described. In order to compare the differences between the embodiments easily, the identical components in each of the following embodiments are marked with identical symbols.

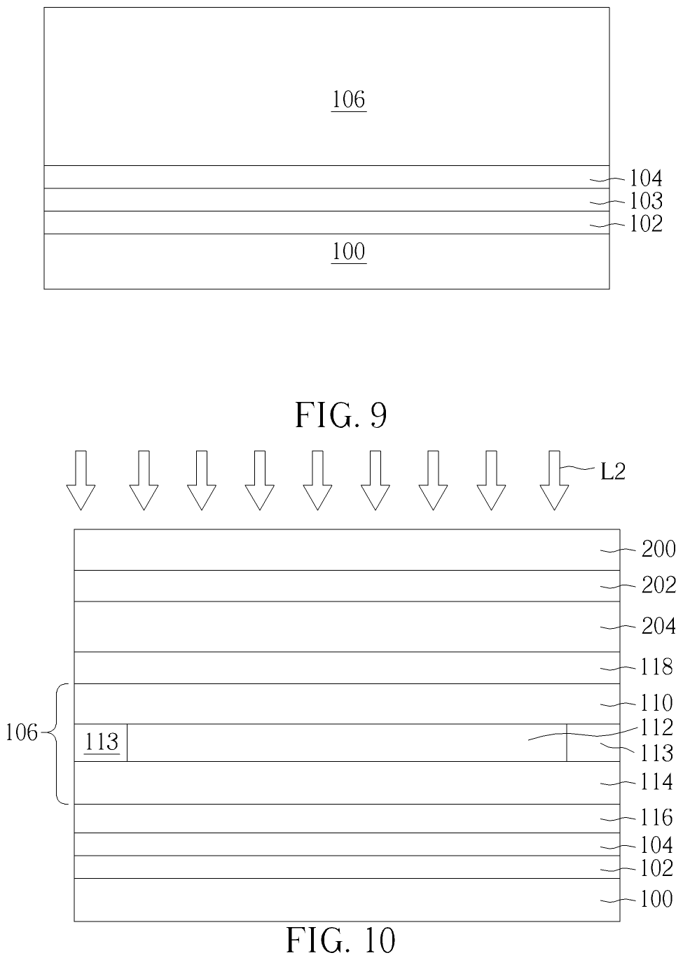

Referring to FIG. 9, which shows the schematic diagram of a display device according to a second embodiment of the present disclosure. In this embodiment, a silicon nitride film 103 may be further formed between the polymer film 104 and the hydrogen containing structure 102 (such as an amorphous silicon film). The purpose of forming the silicon nitride film 103 is that the silicon nitride film 103 may better bonding with the polymer film 104 and the hydrogen containing structure 102, or to decrease the degree of bending of the flexible polymer film 104 during fabrication. In the subsequent steps, the silicon nitride film 103 will be removed with the hydrogen containing structure 102 and the temporary substrate 100 after the laser beam process (the LLO process).

Except for the features mentioned above, the other components, material properties, and manufacturing method of this embodiment are similar to the first embodiment detailed above and will not be redundantly described.

Referring to FIGS. 10-11, which show the schematic diagrams of a display device according to a third embodiment of the present disclosure. In this embodiment, a second temporary substrates 200 and a second hydrogen containing structure 202 may be additionally formed at an opposite side of the display element 106. The second hydrogen containing structure 202 may be disposed between the second temporary substrates 200 and a second polymer film 204. In other words, in this embodiment, the display element 106 is disposed between the polymer film 104 and the second polymer film 204. Besides, in this embodiment, taking the display element 106 is a LCD-type display element as an example, the display element 106 may include a color filter (CF) layer 110, a liquid crystal (LC) layer 112, a sealant layer 113, and a thin film transistor (TFT) layer 114. Besides, the display element 106 can be disposed between one buffer layer 116 and another buffer layer 118, but not limited thereto. The material of the buffer layer 116 or the buffer layer 118 can include oxide (e.g. silicon oxide (SiOx)), nitride (e.g. silicon oxide (SiNy)), or a combination thereof, but not limited thereto. The purpose of forming the buffer layer 116 or the buffer layer 118 is to improve the adhesion between the polymer film 104 (or the second polymer film 204) and the display element 106.

As shown in FIG. 10, the second hydrogen containing structure 202 may be irradiated by a second laser beam L2, and the second hydrogen containing structure 202 can be removed with the second temporary substrates 200 easily from the second polymer film 204. The parameters of laser beam L2 may be the same or similar to that of the laser beam L1 described above, the description will not be repeated here.

As shown in FIG. 11, after the hydrogen containing structure 102 and the second hydrogen containing structure 202 are removed, other components may be further formed on at least one side of the display element 106. For example, a polarizer 300 and a backlight module 302 are disposed at opposite sides of the display element 106, respectively. In one example, another polarizer (not shown) may be disposed between the polymer film 104 and the backlight module 302. The above components are known in the art and will not be described here. In addition to this, other elements may be additionally formed, and the present disclosure is not limited thereto.

In another embodiment of the present disclosure, the hydrogen containing structures 102 and 202 may be removed by different methods. For example, one of the hydrogen containing structures 102 and 202 can be removed by the laser lift-off (LLO) process mentioned above, and the other hydrogen containing structure may be removed by a mechanical lift-off (MLO) process. The MLO process belongs to the well-known technology in the art, and will not be described here. It should also be within the scope of the present disclosure. However, the present disclosure is not limited thereto, other suitable lift-off processes can be used in the present disclosure.

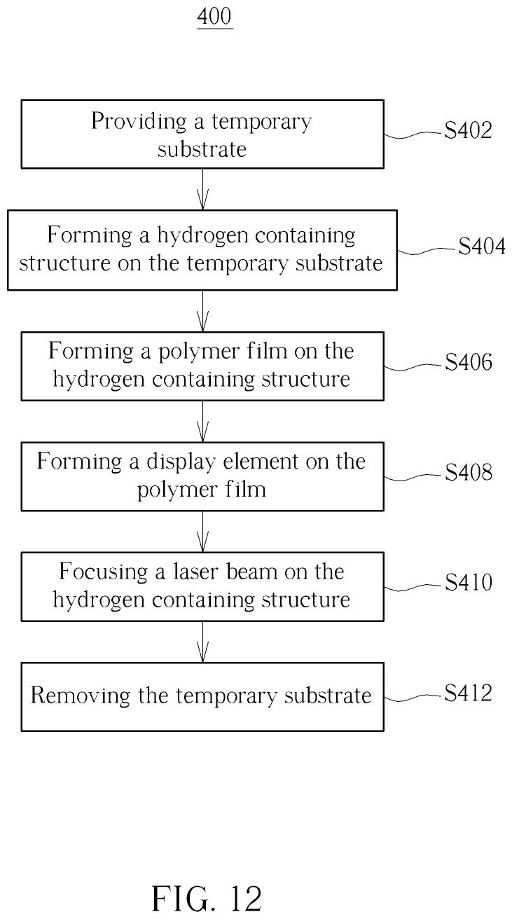

FIG. 12 shows the flow chart of the method for separating a display device from a supporting substrate according to one embodiment of the present disclosure. Please refer to FIG. 8 and please also refer to FIGS. 1-2 and 7-11 mentioned above, a method 400 includes: step 402: providing a temporary substrate (100); step 404: forming a hydrogen containing structure (102) on the temporary substrate (100); step 406: forming a polymer film (104) on the hydrogen containing structure (102); step 408: forming a display element (106) on the polymer film (104); step 410: focusing a laser beam (L1) on the hydrogen containing structure (102); and step 412: removing the temporary substrate (100). However, the above step flow is only an example of the disclosure, and the present disclosure is not limited thereto, the present disclosure may be adjusted based on the above steps (for example, adding or deleting some steps).

In summary, the present disclosure provides a method for separating a display device from a supporting substrate to reduce the degree of deforming or damaging the display device when debonding the display device formed on the supporting substrate. By the method provided by the present disclosure, the quality or production yield of the display device can be improved.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method for manufacturing a display device, comprising following steps:
providing a temporary substrate;
forming a hydrogen containing structure on the temporary substrate;
forming a polymer film on the hydrogen containing structure;
forming a display element on the polymer film;
focusing a laser beam on the hydrogen containing structure; and
removing the temporary substrate, wherein a thickness of the hydrogen containing structure is greater than or equal to 30 nm and less than 50 nm.

2. The method for manufacturing the display device according to claim 1, wherein the hydrogen containing structure comprises an amorphous silicon film.

3. The method for manufacturing the display device according to claim 2, wherein the amorphous silicon film is removed in the step of removing the temporary substrate.

4. The method for manufacturing the display device according to claim 2, wherein the hydrogen containing structure further comprises a silicon nitride film disposed between the polymer film and the amorphous silicon film.

5. The method for manufacturing the display device according to claim 5, wherein the hydrogen containing structure is removed in the step of removing the temporary substrate.

6. The method for manufacturing the display device according to claim 1, wherein a peak wavelength of the laser beam ranges from 306 nm to 310 nm.

7. The method for manufacturing the display device according to claim 6, wherein a transmittance of the temporary substrate corresponding to the peak wavelength of the laser beam is greater than 0.75 and less than or equal to 1.

8. The method for manufacturing the display device according to claim 1, wherein in the step of forming the hydrogen containing structure, a hydrogen gas is introduced into a chamber.

9. The method for manufacturing the display device according to claim 1, wherein the display element comprises a color filter layer.

10. The method for manufacturing the display device according to claim 1, wherein after the temporary substrate is removed, a roughness of an exposed surface of the polymer film is less than 5 nm and greater than 0 nm.

11. The method for manufacturing the display device according to claim 1, wherein the display element comprises a thin film transistor layer

12. The method for manufacturing the display device according to claim 1, further comprising disposing a polarizer on the polymer film.

13. The method for manufacturing the display device according to claim 1, wherein the display element comprises a liquid crystal (LC) cell, an organic light emitting diode (OLED), a quantum-dot light emitting diode (LED), a micro LED, a mini LED, or an inorganic LED.

14. The method for manufacturing the display device according to claim 1, further comprising disposing at least one buffer layer positioned between the polymer film and the display element.

15. The method for manufacturing the display device according to claim 14, wherein a material of the buffer layer comprises oxide, nitride, or a combination thereof.

16. The method for manufacturing the display device according to claim 1, wherein the polymer film contacts the hydrogen containing structure directly.

17. The method for manufacturing the display device according to claim 1, further comprising forming a second hydrogen containing structure and a second temporary substrate on a side of the display element away from the polymer film.

18. The method for manufacturing the display device according to claim 17, further comprising focusing a second laser beam on the second hydrogen containing structure.

19. The method for manufacturing the display device according to claim 1, wherein an energy intensity of the laser beam is greater than 400 mJ/cm².

20. The method for manufacturing the display device according to claim 1, wherein an energy intensity of the laser beam is greater than or equal to 420 mJ/cm² and less than or equal to 450 mJ/cm².
